(19) United States
(12) Patent Application Publication
(10) Pub. No.: US 2005/0260846 A1
(43) Pub. Date: Nov. 24, 2005

(54) Substrate processing method, semiconductor device production method, and semiconductor device

(76) Inventors: Eiichi Kondoh, Nakakoma-Gun (JP); Vincent Vezin, Kyoto-Shi (JP); Kenichi Kubo, Kofu-Shi (JP); Yoshinori Kureishi, Fuchu-Shi (JP); Tomohiro Ohta, Nirasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/190,127

(22) Filed: Jul. 27, 2005

Related U.S. Application Data
(63) Continuation of application No. PCT/JP03/16989, filed on Dec. 26, 2003.

(30) Foreign Application Priority Data
Jan. 27, 2003 (JP) 2003-017949

(51) Int. Cl. H01L 21/20; H01L 21/4763

(52) U.S. Cl. 438/622; 438/629; 438/626; 438/687; 438/627

(57) ABSTRACT

A substrate processing method is disclosed that, when forming a copper film on a miniaturized pattern with a copper diffusion prevention film being formed thereon, allows cleaning the copper diffusion prevention film on a substrate by using a supercritical medium, and allows the copper film to be formed by using the supercritical medium while preventing void occurrence and ensuring good adhesiveness with the miniaturized pattern. The substrate processing method includes a first step of supplying a first processing medium including a supercritical medium on a substrate and cleaning a film including a metal on a surface of the substrate; and a second step of supplying a second processing medium including the supercritical medium on the substrate, and forming a copper film.

### CROSS-REFERENCE TO RELATED APPLICATION

This application is a U.S. continuation application filed under 35 USC 111(a) claiming benefit under 35 USC 120 and 365(c) of PCT application JP2003/016989, filed on Dec. 26, 2003 based on Japanese Priority Patent Application No. 2003-017949 filed on Jan. 27, 2003. The entire contents of these applications are hereby incorporated by reference.

### TECHNICAL FIELD

The present invention relates to a method of processing a substrate, a method of producing a semiconductor device, and a semiconductor device.

### BACKGROUND OF THE INVENTION

In recent years and continuing, along with increasingly improved performance of semiconductor devices, the integration degree of the semiconductor devices is becoming higher, hence the requirement for miniaturization of the semiconductor devices is becoming stronger, and development for this is being carried out in a region with a design rule of interconnections being from 0.13 μm to 0.10 μm or shorter. In addition, the aluminum material of the interconnection in the related art has been replaced by copper, which has a low resistance and produces little influence on interconnection delay.

Therefore, the combination of a technique of forming a copper film and a technique of miniaturizing the interconnections has become an important key technology in the technique of miniaturizing multi-layer interconnections.

Concerning the techniques of forming a copper film, sputtering, CVD, and plating are well known methods. However, any of them has only a limited coverage when considering miniaturized interconnections, and it is difficult to form a copper film efficiently on a miniaturized pattern having a high aspect ratio and a line width below 0.1 μm.

To solve this problem, a method of forming a copper film by using a supercritical medium is proposed in order to efficiently form the copper film on the miniaturized pattern (for example, reference can be made to “Deposition of Conformal Copper and Nickel Films from Supercritical Carbon Dioxide”, SCIENCE Vol. 294, Oct. 5, 2001, www.sciencemag.org). According to this reference, a precursor compound, which includes copper for forming a copper film by using supercritical carbon dioxide (CO₂), is dissolved, and a copper film is formed. The “supercritical condition” indicates a condition in which the material has a temperature/pressure exceeding an intrinsic value (critical value) of the material, and the material processes both gaseous and liquid properties.

For example, in a medium of the aforesaid supercritical carbon dioxide, the solubility of the copper film formation precursor, namely, the precursor compound including copper, is higher, but the viscosity is low, and the diffusion capability is high. Due to this, it is possible to form a copper film on a miniaturized pattern having a high aspect ratio, as described above.

In the above mentioned reference, a technique is introduced for burying copper in a miniaturized pattern.

However, when practically fabricating a semiconductor device by using the aforesaid copper film formation technique, for example, in order to prevent diffusion of copper into an insulating film between copper interconnections, it is necessary to form a diffusion prevention film between the copper film and the insulating film wherein the diffusion prevention film is formed to prevent diffusion of copper. The diffusion prevention film also serves as a contact layer for improving adhesiveness between the copper film and the insulating film.

It is known that a metal film, a metal nitride film, or a stacked film of the metal film and the metal nitride film may be used as the aforesaid copper diffusion prevention film. Specifically, Ti, Ta, W, TiN, TaN, WN and so on may be used.

In the related art, the aforesaid copper diffusion prevention film is formed by sputtering. In recent years, CVD has been also frequently used because it results in good coverage.

After the copper diffusion prevention film is formed, however, when forming the copper film, for example, the surface of the copper diffusion prevention film is covered by an oxide film of the copper diffusion prevention film, and the surface is not clean; thereby, the following problems occur. Specifically, adhesiveness between the copper film and the copper diffusion prevention film declines, or voids may occur when forming the copper film on the miniaturized pattern with the copper diffusion prevention film being thereon, and this may cause problems when burying the copper film. Further, when it is desired to remove the oxide film by dry etching or sputtering, it is required to lower the pressure, and it is necessary to prepare a different device for a process of burying the copper film by using a supercritical medium. Between the devices for different purposes, it is required to convey a substrate under processing in and out, and this reduces the production rate.

### DISCLOSURE OF THE INVENTION

Accordingly, a general object of the present invention is to provide a novel and useful substrate processing method, a semiconductor device production method, and a semiconductor device able to solve one or more problems of the related art.

A more specific object of the present invention is to provide a substrate processing method which, when forming a copper film on a miniaturized pattern with a copper diffusion prevention film being formed thereon, allows cleaning the copper diffusion prevention film on a substrate by a cleaning method employing a supercritical medium, and allows the copper film to be formed by employing the supercritical medium without voids and having good adhesiveness with the miniaturized pattern.

According to an aspect of the present invention, there is provided a substrate processing method, comprising a first step of supplying a first processing medium including a supercritical medium on a substrate to be processed, and cleaning a film on the surface of the substrate, the film including a metal; and a second step of supplying a second processing medium including the supercritical medium on the substrate, and forming a copper film.

According to the present invention, when forming a copper film on a miniaturized pattern with a copper diffusion prevention film being formed thereon, the copper diffusion prevention film on the substrate can be cleaned by a method employing a supercritical medium, and the copper film can be formed by employing the supercritical medium. Due to this, it is possible to form a copper film without voids and having good adhesiveness with the miniaturized pattern.

In addition, if the substrate processing method of the present invention is applied to fabricate a semiconductor device, when forming a copper film on a miniaturized pattern with a copper diffusion prevention film being formed thereon, the copper diffusion prevention film on the substrate can be cleaned by a method employing a supercritical medium, and the copper film can be formed by employing the supercritical medium. Due to this, it is possible to form a copper film without voids and having good adhesiveness with the miniaturized pattern.

These and other objects, features, and advantages of the present invention will become more apparent from the following detailed description of preferred embodiments given with reference to the accompanying drawings.

### BRIEF DESCRIPTION OF THE DRAWINGS

FIG. 1 is a flowchart illustrating a substrate processing method according to a first embodiment of the present invention;

FIG. 2 is a diagram illustrating a substrate processing device 500 able to perform substrate processing by using the substrate processing method of the present invention;

FIG. 3 is a flowchart illustrating the first step as a third embodiment of the present invention;

FIG. 4 is a flowchart illustrating a modification to the third embodiment;

FIG. 5 is a flowchart illustrating a modification to the third embodiment;

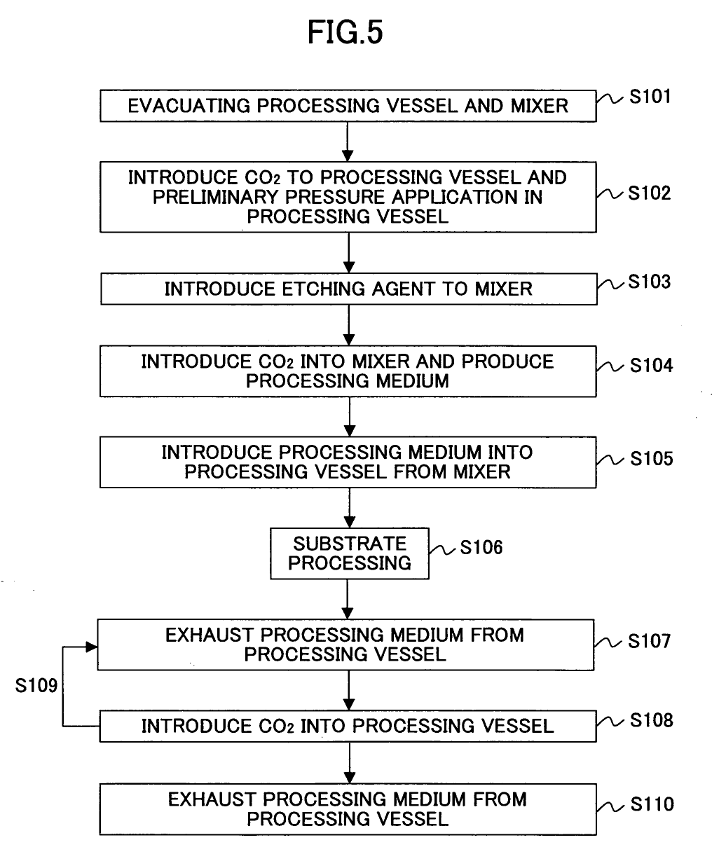

FIG. 6A and FIG. 6B show examples of high solubility of the precursor for copper film formation in the supercritical CO₂;

FIG. 7 is a flowchart illustrating a process as a modification of the process described in the fifth embodiment;

FIG. 8 is a flowchart illustrating the second step in which a liquid material is used as the precursor for copper film formation;

FIG. 9 is a flowchart illustrating the second step as an eighth embodiment of the present invention;

FIG. 10 is a diagram illustrating the substrate processing device 500A for performing the first step;

FIG. 11 is a diagram illustrating the substrate processing device 500B for performing the second step;

FIG. 12A through FIG. 12C are cross-sectional views illustrating a process for fabricating a semiconductor device by employing the substrate processing method of the present invention; and

FIG. 13A through FIG. 13C are cross-sectional views illustrating the process for fabricating the semiconductor device following the step in FIG. 12C.

### BEST MODE FOR CARRYING OUT THE INVENTION

Below, preferred embodiments of the present invention are explained with reference to the accompanying drawings.

First Embodiment

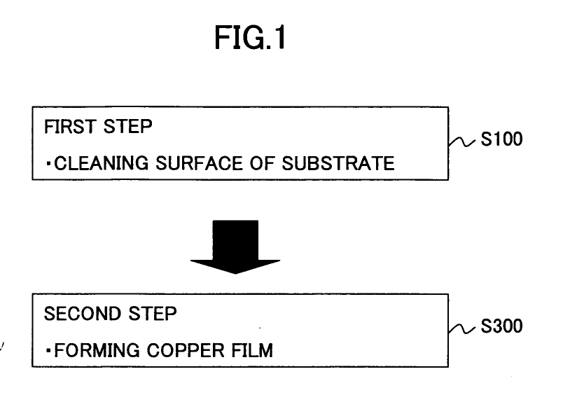

FIG. 1 is a flowchart illustrating a substrate processing method according to a first embodiment of the present invention.

In this process, by using the aforesaid supercritical carbon dioxide (CO₂), the following treatments are performed.

As illustrated in FIG. 1, generally, the substrate processing method includes a first step (indicated by S100 in FIG. 1) of cleaning the surface of a substrate to be processed, and a second step (indicated by S300 in FIG. 1) of forming a copper film.

First, in the first step, using a processing medium obtained by dissolving an etching agent in the supercritical CO₂, an oxide film formed on a copper diffusion prevention film on the substrate is removed. With the oxide film being removed, adhesiveness between the copper diffusion prevention film and a copper film formed in the following second step is improved; further, it is possible to prevent formation of voids in the copper film caused by influence from the oxide film, and to form a film having good quality.

Second Embodiment

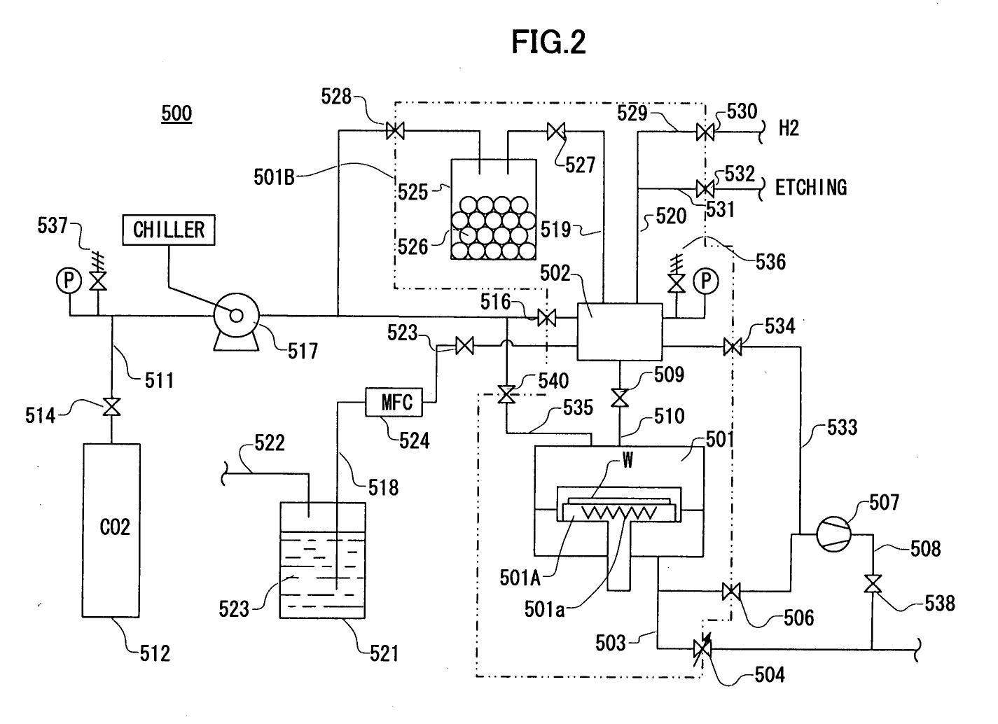

FIG. 2 is a diagram illustrating a substrate processing device 500 able to perform substrate processing by using the substrate processing method of the present invention.

As illustrated in FIG. 2, generally, the substrate processing device includes a processing vessel 501, in which a substrate stand 501A having a built-in substrate heater 501a is provided, a mixer 502 which supplies a processing medium including a supercritical medium used for substrate processing to the processing vessel 501, and an exhaust line 503 which exhausts gas from the processing vessel 501.

On the substrate stand 501A, a semiconductor wafer W, which is a substrate to be processed, is located. The mixer 502 supplies the processing medium including the supercritical medium to the processing vessel 501 for substrate processing. The processing medium after the substrate processing is exhausted through the exhaust line 503 when a valve 504 is opened, and the processing vessel 501 is nearly at atmospheric pressure. If the inside of the processing vessel 501 is below atmospheric pressure due to evacuation, a valve 506 and a valve 538 are opened, and a vacuum pump 507 can pump the processing vessel 501 down to a vacuum through a vacuum exhaust line 508.

In the processing vessel 501, the mixer 502, which produces the processing medium and supplies the processing medium to the processing vessel 501, is connected to a feed line 510 to which a valve 509 is attached. In the mixer 502, the supercritical medium is mixed with a certain additive to produces the processing medium, and the processing medium is supplied to the processing vessel 501.

A liquid CO₂ supplier 512 is connected to a pressure application line 511, and the pressure application line 511 is connected to the mixer 502. In the pressure application line 511, a valve 514 and a valve 516 are opened to supply CO₂ from the liquid CO₂ supplier 512 to the mixer 502. Here, by a pressure pump 517 provided in the pressure application line 511, a pressure is applied to the CO₂ supplied to the mixer 502 until a supercritical condition occurs. The pressure pump 517 is cooled by a chiller to prevent a temperature rise during operation and enable pressure application to liquid CO₂.

In addition, a heater is provided in the mixer 502, the processing vessel 501, a feed line 510, and a part of the pressure application line 511 to heat them, so that the CO₂ exceeds the supercritical point to stay in the supercritical condition. In the substrate processing device 500, an area is indicated by 501B, in which the heater is provided for heating so as to produce the supercritical condition.

Further, a liquid material feed line 518, a solid material feed line 519, and a gas feed line 520 are connected to the mixer 502 to dissolve or mix a liquid material, a solid material, and a gas in the supercritical medium to produce the processing medium and supply the processing medium to the processing vessel 501.

Below, an explanation is made of the liquid material feed line 518. The liquid material feed line 518 is connected to a liquid material container 521 which contains the liquid material 523. An inert gas is supplied by a gas line 522 connected to an inert gas supplier to the liquid material container 521 to create pressure in the liquid material container 521, and when a valve 523 is opened, the liquid material 523 is supplied from the liquid material feed line 518 to the mixer 502. In this process, a mass flow rate controller 524 set in the liquid material feed line 518 controls the liquid material 523 to flow at a specified flow rate. The liquid material 523 is mixed with the supercritical medium in the mixer 502 and is supplied to the processing vessel 501.

Below, an explanation is made of the solid material feed line 519. The solid material feed line 519 supplies a solid material 526 dissolved in CO₂, which is the supercritical medium, to the mixer 502 together with the supercritical medium in the following way.

A valve 528 and the valve 514 are opened in advance, and from the liquid CO₂ supplier 512, liquid CO₂ is supplied to a solid material container 525 through the pressure application line 511. Here, by the pressure pump 517 provided in the pressure application line 511, pressure is applied to the CO₂ supplied to the solid material container 525 until a supercritical condition occurs. The solid material 526 is sufficiently dissolved in CO₂, producing the supercritical medium, to produce the processing medium beforehand. Afterward, the valve 527 is opened, and the processing medium is supplied to the mixer 502, which is fully filled with the supercritical medium beforehand. When the valve 509 is opened, the processing medium supplied to the mixer 502 is supplied to the processing vessel 501 through the feed line 510.

Below, an explanation is made of the gas material feed line 520. The gas material feed line 520 is connected to a H₂ feed line 529 having a valve 530, and an etching agent feed line 531 having a valve 532 so as to supply H₂ and an etching agent to the mixer 502. The thus supplied H₂ and the etching agent are mixed with the supercritical medium in the mixer 502 and are supplied to the processing vessel 501.

In this way, the substrate processing device 500 is able to use the processing medium obtained by dissolving or mixing a liquid material, a solid material, and a gas in the supercritical medium to process the substrate.

The pressure application line 511 is connected to the processing vessel 501 through a preliminary pressure application line 535 having a valve 540 so as to enable increasing the pressure in the processing vessel 501 through the preliminary pressure application line 535 without going through the mixer 502.

In addition, for sake of safety, a pressure releasing valve 536 and a pressure releasing valve 537 are provided in the mixer 502 and the pressure application line 511, respectively, so as to prevent an abnormal rise in pressure. The processing vessel 501 is adjusted to be at a preset pressure with a back-pressure regulating valve 504 in the exhaust line 503; hence, it is capable of preventing an abnormal rise in pressure.

Below, descriptions are made of a process flow of executing the substrate processing method of the present invention by using the substrate processing device 500.

Third Embodiment

As described above, generally, the substrate processing method of the present invention includes the first step and the second step.

Below, descriptions are made of detailed process flows of the first step and the second step, respectively, with reference to the accompanying drawings. Below, the same reference numbers are assigned to the same elements as described previously, and overlapping descriptions are omitted.

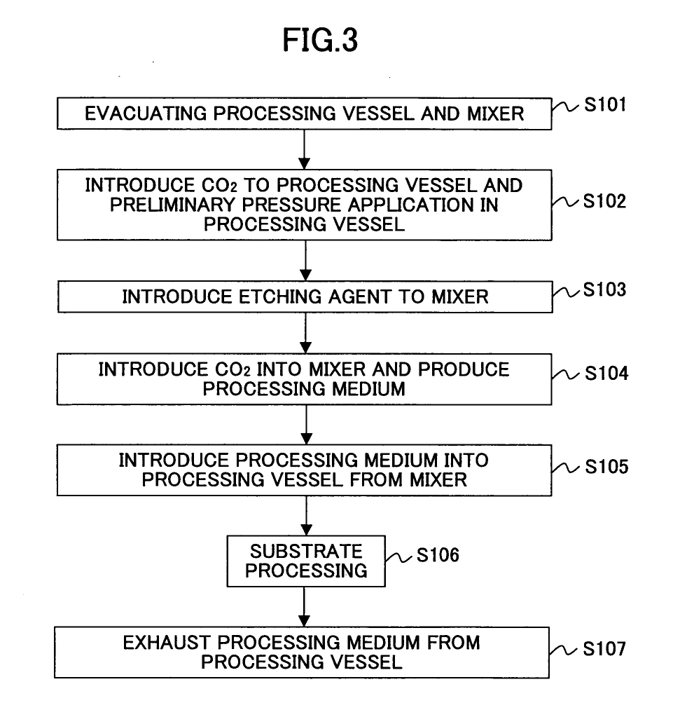

First, FIG. 3 is a flow chart illustrating the first step as a third embodiment of the present invention.

As illustrated in FIG. 3, the first step includes step S101 through step S107.

In step S101, when processing the wafer W laid on the substrate stand 501A, the valves 506, 534, and 538 are opened, and the vacuum pump 507 evacuates the processing vessel 501 and the mixer 502. After pumping, the valves 506, 534, and 538 are closed. Alternatively, without opening the valve 534 but opening the valve 509, the mixer 502 can also be evacuated through the processing vessel 501.

In step S102, the valve 514 and the valve 540 are opened to supply CO₂ to the processing vessel 501. In this process, because pressure is applied by using the pressure pump 517, and the area 501B, which covers the processing vessel 501 and the mixer 502, is heated by the heater, CO₂ in the processing vessel 501 reaches the supercritical condition. In addition, because the pressure pump 517 is cooled by a chiller, it is possible to prevent CO₂ from transiting to a gas state; thus the pressure is applied to CO₂ in a liquid state.

Here, the supercritical points of CO₂ are: a temperature of 31.0° C. and a pressure of 7.38 MPa. The processing vessel 501 is adjusted to be at a temperature and a pressure higher than the supercritical points, and thus, the processing vessel 501 is fully filled with the supercritical CO₂. After that, the valve 514 and the valve 540 are closed.

In this way, by fully filling the processing vessel 501 with the supercritical CO₂ in advance, when the processing medium including the supercritical CO₂ is introduced into the processing vessel 501, the processing medium can be maintained in the supercritical state, and thereby, maintaining a supercritical medium at a high concentration. Further, with the processing vessel 501 being at a certain pressure, the wafer W is heated by the substrate heater 501a to a temperature from 100° C. to 400° C.

Next, in step S103, by opening the valve 532, an etching agent is supplied from the etching agent feed line 531 to the mixer 502, which is at a lowered pressure. The mixer 502 is filled with the etching agent, and after a certain time period, the valve 532 is closed.

Next, in step S104, the valve 516 is opened, CO₂ is introduced into the mixer 502 by the pressure pump 517, which CO₂ cooled by the chiller in advance, and pressure is applied to the CO₂ until a supercritical condition occurs. Thereby, the etching agent is sufficiently diffused and mixed to produce a processing medium. The valve 516 is closed at a certain supercritical pressure.

Next, in step S105, the valve 509 is opened, the processing medium including the supercritical CO₂ is introduced into the processing vessel 501 from the mixer 502. In addition, the valve 516 may be opened or closed for pressure adjustment when necessary, and the processing medium in the mixer 502 is transported to the processing vessel 501.

Next, in step S106, with the above processing medium, substrate processing is performed.

Here, the preliminary pressure application to the processing vessel 501 in step 102 may be performed between step 104 and step 105.

Because of the supercritical CO₂ and the etching agent, reactions occur to remove a metal film or a metal nitride film on the surface of the substrate, for example, Ta/TaN oxide films formed on a surface of a Ta/TiN film.

The etching agent may be a chelating agent, a halogen compound, an acid, or an amine.

For example, when the chelating agent is H(hexafluoroacetylacetonate), the following reactions occur to remove the oxide film on the Ta film or the TiN film.
TaOₓ+2×H(hfac)→Ta(hfac)ₓ+H₂O
TaNOₓ+2×H(hfac)→Ta(hfac)+H₂O+N₂

In addition, with an acid, such as HCl, the following reactions occur, and the oxide film can be removed similarly.
TaOₓ+HCl→TaClₓ+H₂O
TaNOₓ+HCl→TaClₓ+H₂O+N₂

In addition, as a halogen compound, ClF3 can be used, and in this case, in step S103 shown in FIG. 3, the valve 530 is opened to further introduce H₂ into the mixer 502 to add H₂ to the processing medium. Thereby, the following reactions occur, and a similar effect is obtainable.
TaOₓ+ClF₃+H₂→TaClₓF_{y}+H₂O+O₂
TaNOₓ+ClF₃+H₂→TaClₓF_{y}+H₂O+N₂+O₂

In this way, with the oxide film on the Ta/TiN film being removed, adhesiveness between the Ta/TaN film and a copper film formed in the following second step can be improved; further, it is possible to prevent formation of voids caused by influence from the oxide film when forming the copper film, and to form a film having good quality on a miniaturized pattern.

The following materials may also be used as the etching agent, that is, acetylacetone, 1,1,1-trifluoropentane-2,4-dione, 2,6-dimethylpentane-3,5-dione, 2,2,7-trimethyloctane-2,4-dione, 2,2,6,6-tetramethylheptane-3,5-dione, EDTA (ethylenediamine tetraacetic acid), NTA (nitrilotriacetic acid), acetic acid, formic acid, oxalic acid, maleic acid, glycolic acid, citric acid, malic acid, and latic acid.

Next, in step S107, the valves 504 and 538 are opened to exhaust the processing medium in the processing vessel 501 and the mixer 502 to complete the first step.

In the present embodiment, it is exemplified to remove the oxide film formed on the Ta film or the TiN film, but it is possible to apply the same method of the present embodiment to etching oxide films formed on Ti, W, WN, and the same effect as those of the Ta film or the TiN film can be obtained.

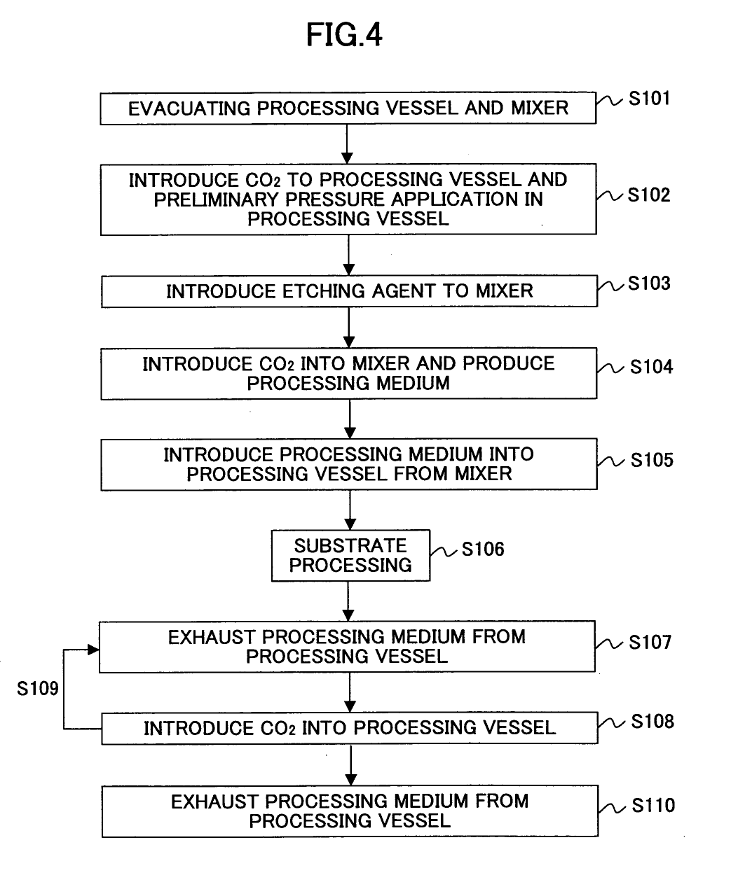

After step S107, a rinsing step as illustrated in FIG. 4 may be further performed.

Fourth Embodiment

FIG. 4 is a flow chart illustrating a modification to the third embodiment. Below, the same reference numbers are assigned to the same elements as described previously, and overlapping descriptions are omitted.

As illustrated in FIG. 4, the steps S101 through S107 are the same as those in the third embodiment in FIG. 3.

In step S108, the valve 504 is closed and the valve 516 is opened to fill the processing vessel 501 and the mixer 502 with the supercritical CO₂. Then, the valve 516 is closed.

Then, in step S110, the valve 504 is opened again to exhaust the supercritical CO₂ in the processing vessel 501 and the mixer 502. Because the step S108 and the step S110 are added, un-reacted processing medium or reaction by-products adhering to the inner wall of the processing vessel 501 or the wafer W can be exhausted out of the processing vessel 501. Further, if necessary, by a step S109, the routine can be returned to step S107 from step S108 so as to repeatedly execute the rinse step in step S108 to remove the aforesaid residues or reaction by-products.

Fifth Embodiment

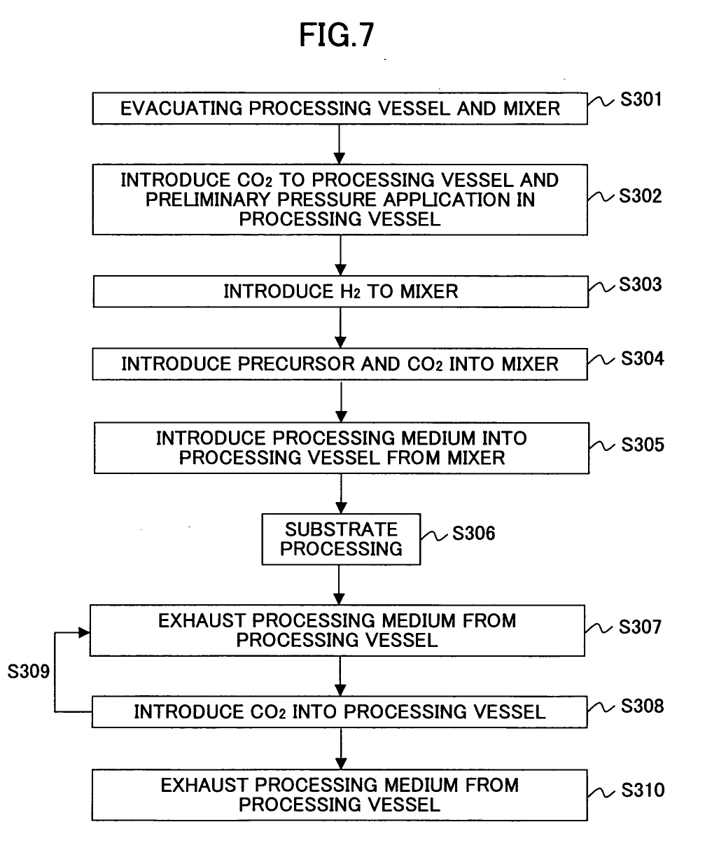

FIG. 7 is a flowchart illustrating the second step as a fifth embodiment of the present invention. The second step is a step of forming a copper film after cleaning the surface in the first step. In order to form the copper film, a solid material or a liquid material may be used as a precursor for copper film formation. The flow chart in FIG. 7 illustrates the process of using the solid material.

In FIG. 7, step S301 and step S302 are the same as step S101 and step S102 in FIG. 3, except that the wafer W is maintained at a temperature from 150° C. to 400° C. by the substrate heater 501a.

In step S303, by opening the valve 530, H₂ is supplied from the H₂ feed line 529 to the mixer 502 up to a specified amount, then the valve 530 is closed. The mixer 502 is fully filled with H₂.

Next, in step S304, the solid material 526, which is contained in the solid material container 525 and serves as the precursor for copper film formation, is introduced into the mixer 502. Before executing step S304, the valves 514 and 528 are opened, so that with the pressure pump 517, the solid material container 525 is adjusted to be at an increased pressure by using CO₂. Because the solid material container 525 is in the area 501B, and is heated by the heater, supercritical CO₂ is produced in the solid material container 525. Because the solubility of the precursor in the supercritical CO₂is high, the solid material 526 serving as the precursor for copper film formation, for example, Cu⁺² (hexafluoroacetylacetonate) 2, is sufficiently dissolved in the supercritical CO₂ to produce the processing medium.

Then in step S304, the valve 527 is opened, and the processing medium is supplied to the mixer 502. Here, in order to maintain the pressure in the solid material container 525, the valve 528 is opened or closed when necessary. After the valve 527 is opened for a certain time period, the valve 527 is closed.

Next, in step S305, the valve 509 is opened, and the processing medium including the supercritical CO₂ is introduced into the processing vessel 501 from the mixer 502. In addition, the valve 516 may be opened or closed for pressure adjustment when necessary to maintain the supercritical state of CO₂.

Next, in step S306, by the following reaction, a copper film is formed on the wafer W, which is the substrate to be processed.
Cu⁺⁺(hfac)₂+H₂→Cu+2H(hfac)

Here, hfac represents hexafluoroacetylacetonate. After a certain time period elapses, the process proceeds to step S307. In the present step, the wafer W is maintained approximately at a temperature from 150° C. to 400° C. by the substrate heater 501a.

Because the supercritical CO₂ has high fluidity and high diffusion capability, for example, the copper film can be efficiently formed even on the bottom or sidewall of a miniaturized pattern below 0.1 μm. In addition, because the surface of the Ta/TaN film, on which the copper film is formed, is cleaned by removing oxide films in the first step, the adhesiveness with the copper film is good, voids are not formed, and good coverage is obtainable.

The subsequent step S307 is the same as step S107 in FIG. 3.

In the present embodiment, Cu⁺² (hexafluoroacetylacetonate) ₂ is used as the precursor for copper film formation; in addition to that, Cu⁺²(acetylacetonate)₂, and Cu⁺²(2, 2, 6, 6-tetramethyl-3, 5-heptanedione)₂ can also be used, and the same effect can be obtained.

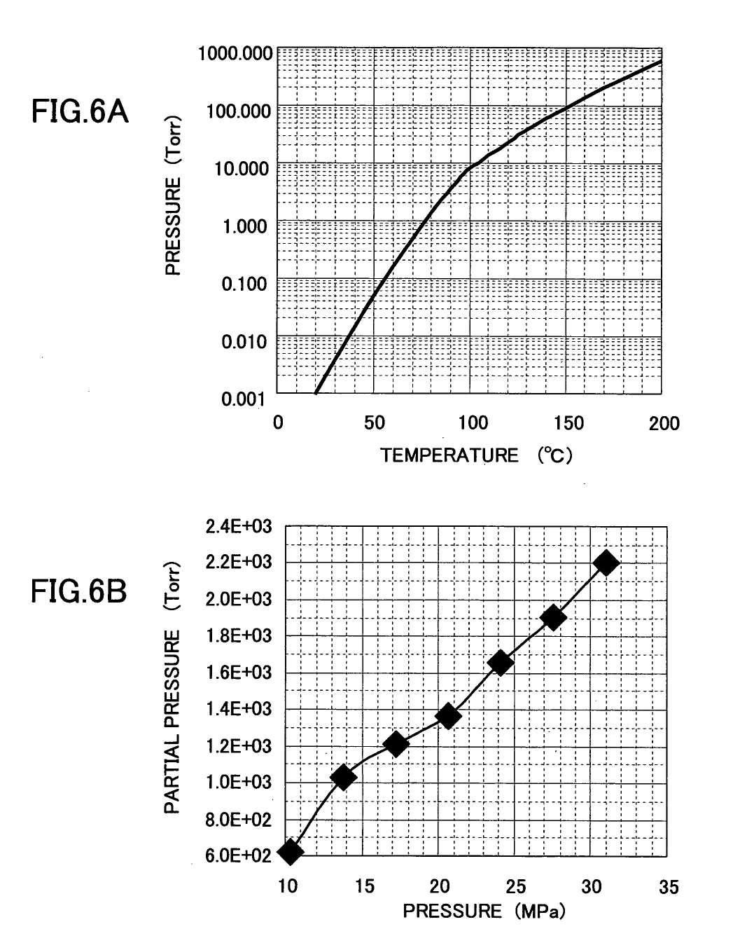

FIG. 6A and FIG. 6B show examples of high solubility of the precursor for copper film formation in the supercritical CO₂. (FIG. 6A is from R. E. Sievers and J. E. Sadlowski, Science 201(1978)217, and FIG. 6B is from A. F. Lagalante, B. N. Hansen, T. J. Bruno, Inorganic Chemistry, 34(1995)).

FIG. 6A shows a saturated vapor pressure curve of Cu⁺² (hexafluoroacetylacetonate)₂.

It is found that the saturated vapor pressure, for example, at 40° C, is about 0.01 Torr.

FIG. 6B shows the partial pressure of Cu⁺²(hexafluoroacetylacetonate) ₂ in the supercritical CO₂ at 313.15 K (40° C.).

As shown in FIG. 6B, in the supercritical region, for example, at 15 MPa, the partial pressure is about 1000 Pa or higher; this indicates that Cu⁺²(hexafluoroacetylacetonate)₂ at a high concentration exists in the supercritical CO₂ compared to the usual saturated condition, and indicates high solubility of Cu⁺² (hexafluoroacetylacetonate)₂ in the supercritical CO₂.

Therefore, by using the supercritical CO₂ which has good fluidity and diffusion capability and high solubility, it is possible to maintain a good film formation speed and to form a film having good coverage on a miniaturized pattern.

Sixth Embodiment

The process described in the fifth embodiment can be modified by adding steps S308 through S310 as shown in FIG. 7.

The steps S308 through S310 constitute the same rinse process as that shown by steps S108 through S110 in FIG. 3, and this process enables removing un-reacted processing medium or reaction by-products adhering to the inner wall of the processing vessel 501 or the wafer W.

Seventh Embodiment

As an example of a process flow of the second step, it is described that a liquid material is used as the precursor for copper film formation.

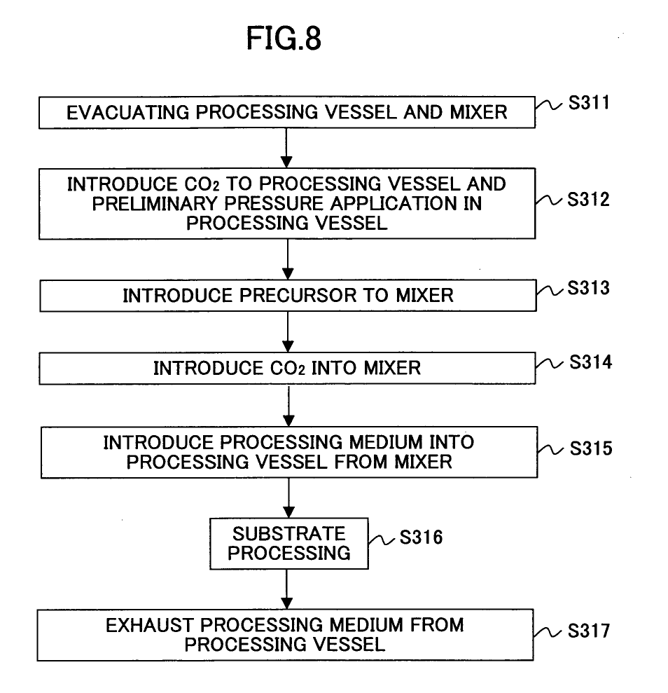

FIG. 8 is a flowchart illustrating the second step in which a liquid material is used as the precursor for copper film formation. Below, the same reference numbers are assigned to the same elements as described previously, and overlapping descriptions are omitted.

In FIG. 8, step S311 and step S312 are the same as step S301 and step S302 in FIG. 7, except that the wafer W is maintained at a temperature from 100° C. to 350° C. by the substrate heater 501a.

In step S313, the liquid material 523 of the precursor for copper film formation, which is supplied from the gas line 522 and is pushed out by an inert gas such as Ar, and for example, is formed from Cu⁺¹(hexafluoroacetylacetonate)(trimethylvinylsilane), is supplied to the mixer 502 at a lowered pressure through the liquid material feed line 518, and the valve 523 is closed after a certain time period elapses.

Next, in step S314, the valve 516 is opened, the supercritical CO₂ is introduced into the mixer 502, and the supercritical CO₂ and the liquid material 523 are sufficiently diffused and mixed to produce the processing medium. After a certain time period elapses, the valve 516 is closed.

Next, in step S315, the valve 509 is opened, and the processing medium including the supercritical CO₂ is introduced into the processing vessel 501 from the mixer 502. In addition, the valve 516 may be opened or closed for pressure adjustment when necessary to maintain the supercritical state of CO₂.

Next, in step S316, by the following reaction, a copper film is formed on the wafer W, which is the substrate to be processed.
Cu⁺(hfac) (tmvs)→Cu⁺(hfac)+tmvs
2Cu⁺(hfac)→Cu+Cu⁺⁺(hfac)₂

Here, hfac represents hexafluoroacetylacetonate, and tmvs represents trimethylvinylsilane. After a certain time period elapses, the process proceeds to step S317. In the present step, the wafer W is maintained approximately at a temperature from 100° C. to 350° C. by the substrate heater 501a.

Because the supercritical CO₂ has high fluidity and high diffusion capability, for example, the copper film can be efficiently formed even on the bottom or sidewall of a miniaturized pattern below 0.1 μm, and good coverage is obtainable.

The subsequent step S317 is the same as step S307 in FIG. 7.

Although Cu⁺¹ (hexafluoroacetylacetonate) (trimethylvinylsilane) is used in the present embodiment as the precursor for copper film formation, a precursor including Cu⁺¹ (hexafluoroacetylacetonate) and silylolefin ligands may also be used. Here, the silylolefin ligands include materials selected from trimethylvinylsilane (tmvs), allyloxytrimethylsilyl (aotms), dimethylacethylene (2-buthyne), 2-methyl-1-hexyne-3-yn (MHY), 3-hexyne-2, 5-dimethoxy (HDM), 1, 5-cyclooctadiene (1, 5-COD), and vinyltrimethoxyxilane (VTMOS), and the same effect can be obtained.

Further, the following additives can be added in the processing medium used in the present embodiment to improve the quality of the formed copper film.

For example, by adding H₂O to the processing medium, the incubation time is shortened when growing a copper film on the copper diffusion prevention film in the third and fourth embodiments, and thus the film formation speed can be improved practically.

In addition, by adding (CH₃)I or (C₂H₅)I when forming a copper film on a miniaturized pattern, even when forming a via-hole below 0.1 μm, a high quality copper film without voids can be formed. (Reference can be made to Kew-Chan Shim, Hyun-Bae Lee, Oh-Kyum Kwon, Hyung-Sang Park, Wonyong Koh and Sang-Won Kang, “Bottom-up Filling of Submicrometer Features in Catalyst-enhanced Chemical Vapor Deposition”, Journal of Electrochemistry Society 149(2), (2002) G109-G113.)

Eighth Embodiment

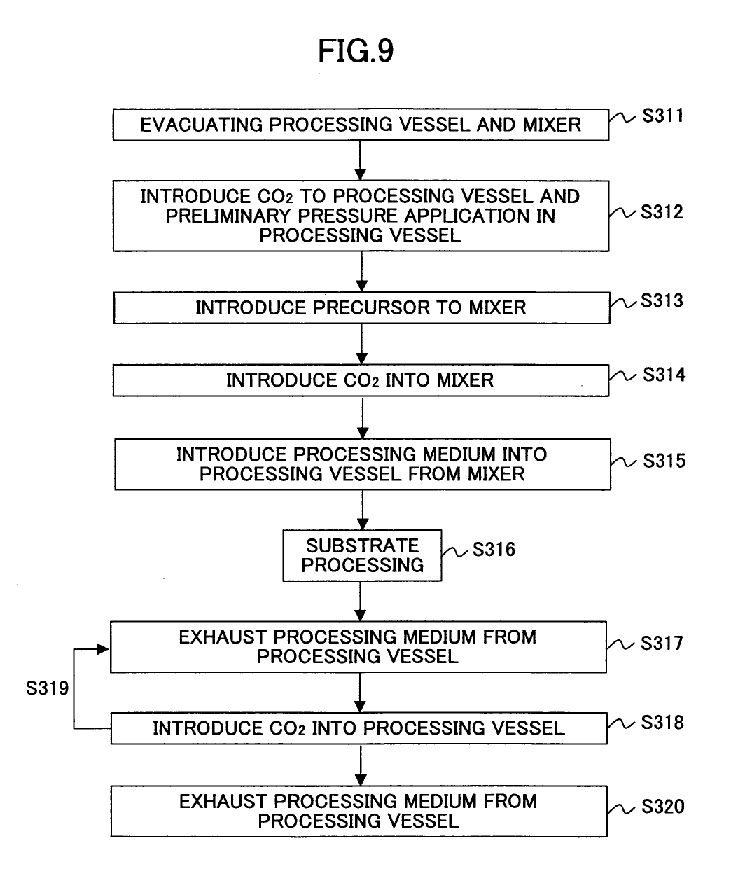

The process described in the seventh embodiment can be modified as shown in FIG. 9. Below, the same reference numbers are assigned to the same elements as described previously, and overlapping descriptions are omitted.

FIG. 9 is a flowchart illustrating the second step as an eighth embodiment of the present invention.

In FIG. 9, steps S318 through S320 constitute the same rinse process as that shown by steps S108 through S110 in FIG. 3, and this process enables removing un-reacted processing medium or reaction by-products adhering to the inner wall of the processing vessel 501 or the wafer W.

Ninth Embodiment

In the above, the first step and the second step are described. Both the first step and the second step are performed in the substrate processing device 500.

However, as described below, the first step and the second step can be performed in different substrate processing devices or processing vessels. For example, as illustrated below, the first step can be performed in a substrate processing device 500A, and the second step can be performed in a substrate processing device 500B.

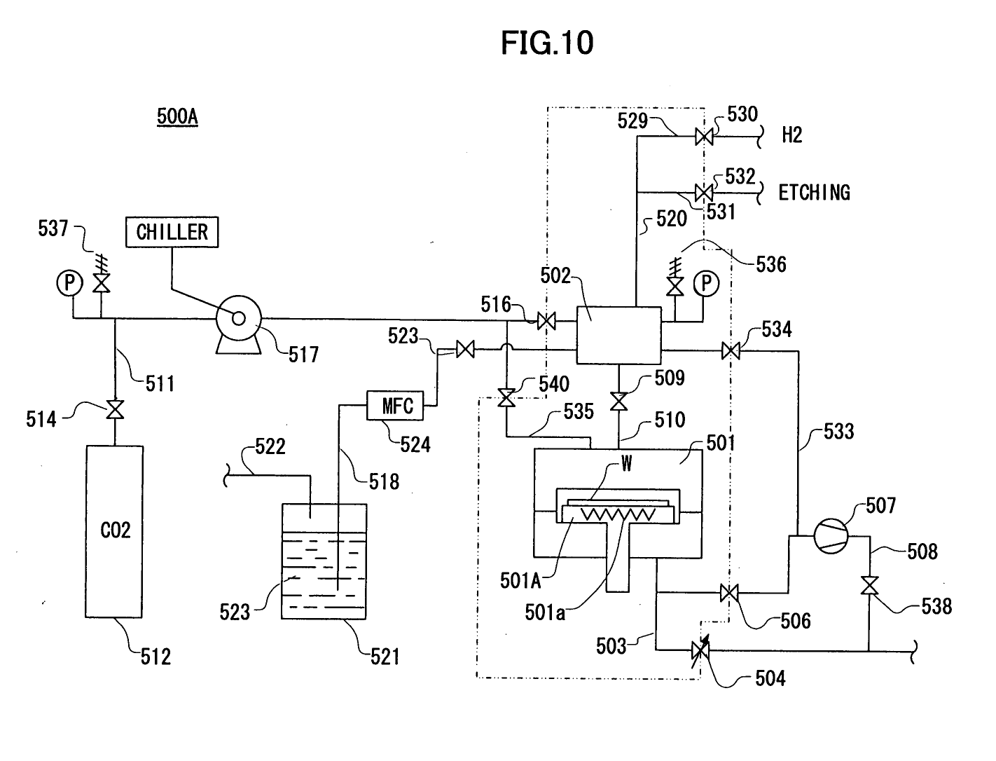

FIG. 10 is a diagram illustrating the substrate processing device 500A for performing the first step. In FIG. 10, the same reference numbers are assigned to the same elements as described previously, and overlapping descriptions are omitted.

As illustrated in FIG. 10, compared to the substrate processing device 500 in FIG. 2, in the substrate processing device 500A, because the second step of forming a copper film is not performed, the solid material feed line 519 and the solid material container 525 are omitted.

In the substrate processing device 500A, only the first step, as described in the third and fourth embodiments, is performed, and in order to perform the second step, the wafer W is conveyed to a substrate processing device 500B.

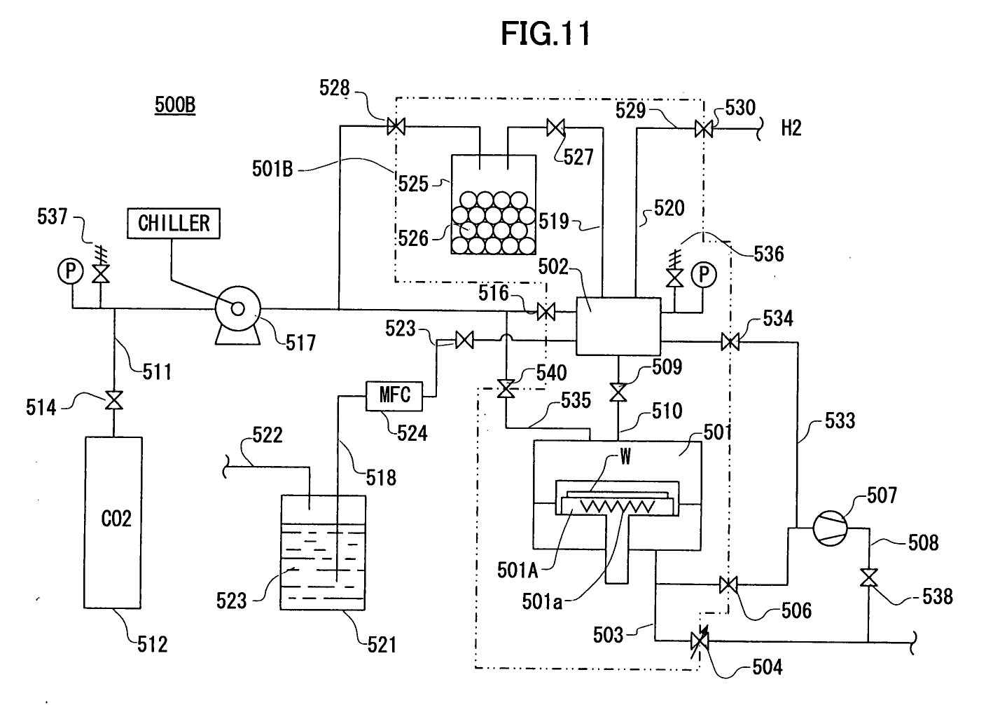

FIG. 11 is a diagram illustrating the substrate processing device 500B for performing the second step. In FIG. 11, the same reference numbers are assigned to the same elements as described previously, and overlapping descriptions are omitted.

As illustrated in FIG. 11, compared to the substrate processing device 500 in FIG. 2, in the substrate processing device 500B, because the first step is not performed, the etching agent feed line 531 is omitted.

In the substrate processing device 500B, the second step, as described in the fifth through eighth embodiments, is performed on the wafer W, which is processed in the first step in the substrate processing device 500A.

When the first step and the second step are performed in different substrate processing devices, the same effect is obtainable as that when the first step and the second step are performed in the same substrate processing device 500.

In addition, when conveying the substrate under processing, it is crucial not to expose the substrate to the atmosphere which includes oxygen, therefore, it is necessary to convey the substrate at a low pressure or in inert gas.

10th Embodiment

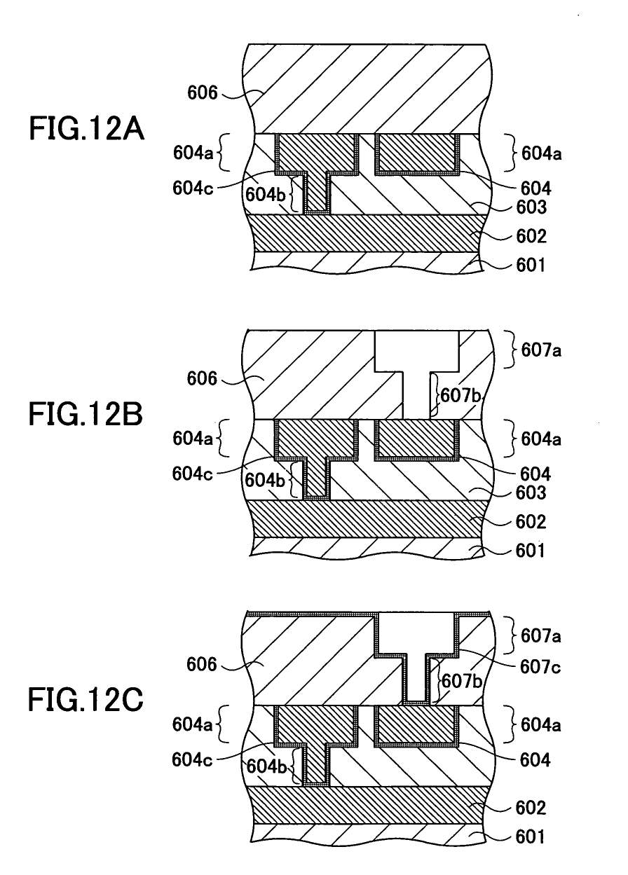

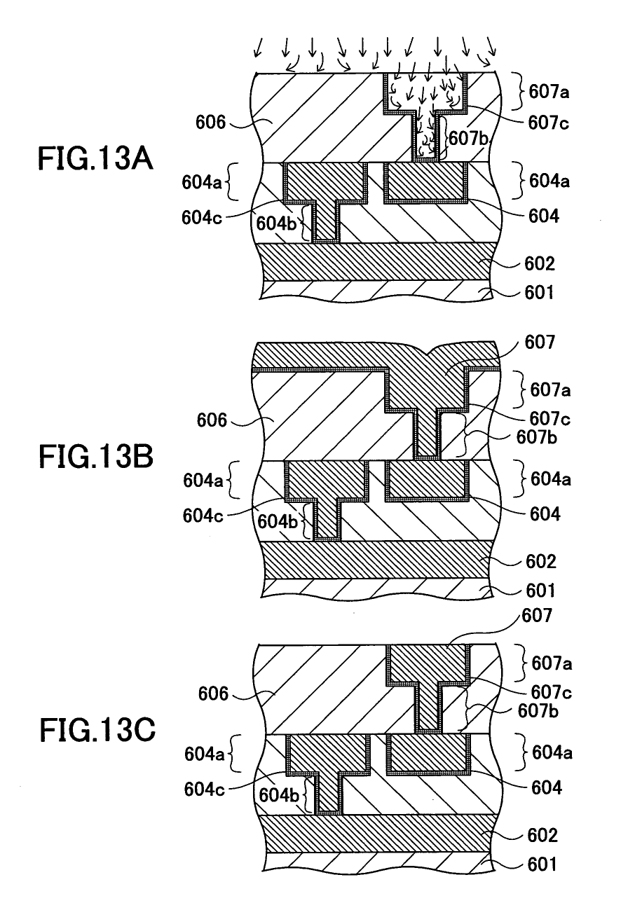

FIG. 12A through FIG. 12C and FIG. 13A through FIG. 13C are cross-sectional views illustrating a process for fabricating a semiconductor device by employing the substrate processing method of the present invention.

First, as illustrated in FIG. 12A, an insulating film, for example, a silicon oxide film 601 is deposited to cover a MOS transistor or other elements (not illustrated) formed on a semiconductor substrate, for example, a silicon substrate. Further, for example, a tungsten (W) interconnection layer (not illustrated) is deposited, which is in electrical connection with the above MOS transistor, and, for example, a copper interconnection layer 602 is formed, which is in electrical connection with the tungsten interconnection layer.

A first insulating layer 603 is deposited on the silicon oxide film 601 to cover the copper interconnection layer 602. A groove 604a and a hole 604b are formed in the first insulating layer 603, and a copper interconnection layer 604 is deposited in the groove 604a and the hole 604b. The copper interconnection layer 604 is in electrical connection with the copper interconnection layer 602. A barrier layer 604c is formed on a contacting surface between the first insulating layer 603 and the copper interconnection layer 604, and on a contacting surface between the copper interconnection layer 602 and the copper interconnection layer 604. The barrier layer 604c prevents diffusion of copper atoms from the copper interconnection layer 604 into the first insulating layer 603, and serves as a contacting layer between the copper interconnection layer 604 and the first insulating layer 603 for improving adhesiveness therebetween. Further, the barrier layer 604c is formed from a metal and a metal nitride, for example, from Ta and TaN.

A second insulating layer 606 is deposited on the copper interconnection layer 604 and the first insulating layer 603 to cover these films. In the present embodiment, by employing the substrate processing method of the present invention, a copper layer and a barrier layer are formed on the second insulating layer 606.

Next, as illustrated in FIG. 12B, a groove 607a and a hole 607b are formed in the second insulating layer 606 by dry etching.

Next, as illustrated in FIG. 12C, a barrier layer 607c is formed on the exposed surfaces of the second insulating layer 606 and the copper interconnection layer 604. For example, the barrier layer 607c is formed from Ta and TaN, specifically, after a Ta film is formed, a TaN film is formed so as to form the Ta/TaN barrier layer 607c.

Next, as illustrated in FIG. 13A, for example, in the substrate processing device 500, the first step of the substrate processing method of the present invention is used to process the substrate. As described above, by using the supercritical CO₂ and the etching agent to clean the substrate to remove the oxide film on the Ta/TaN film, which is formed in the step in FIG. 12C, it is possible to obtain good adhesiveness between the Ta/TaN barrier layer 607c and a copper film formed in subsequent steps, and to prevent formation of voids.

Next, as illustrated in FIG. 13B, for example, the second step of the substrate processing method of the present invention is used to form a copper film 607 on the Ta/TaN barrier layer 607c. Here, as described above, by using the supercritical CO₂, because the supercritical CO₂ in which the precursor for copper film formation is dissolved has high diffusion capability, the copper film 607 can be formed even on the bottom or sidewall of a miniaturized pattern such as the hole 607b and the groove 607a.

Next, as illustrated in FIG. 13C, for example, by CMP, the copper film 607 and the Ta/TaN barrier layer 607c are polished, and formation of a copper interconnection of the second insulating layer 606 is completed.

After this step, further, a (2+n)-th insulating film is formed on the second insulating layer 606 (here, n is an integer), and it is possible to form copper interconnections in these insulating films by employing the substrate processing method of the present invention. In addition, the substrate processing method of the present invention can also be used to clean the barrier layer 604c formed on the first insulating layer 603 and the copper interconnection layer 604.

While the invention has been described with reference to preferred embodiments, the invention is not limited to these embodiments, but numerous modifications could be made thereto without departing from the basic concept and scope described in the claims.

### INDUSTRY APPLICABILITY

According to the present invention, when forming a copper film on a miniaturized pattern with a copper diffusion prevention film being formed thereon, it is possible to clean the copper diffusion prevention film on a substrate by employing a supercritical medium, and to form the copper film by employing the supercritical medium while preventing occurrence of voids and ensuring good adhesiveness with the miniaturized pattern and good coverage.

1. A substrate processing method, comprising:
a first step of supplying a first processing medium including a supercritical medium on a substrate to be processed, and cleaning a film on a surface of the substrate, said film including a metal; and
a second step of supplying a second processing medium including the supercritical medium on the substrate, and forming a copper film.

2. The substrate processing method as claimed in claim 1, wherein the film including a metal is a copper diffusion prevention film.

3. The substrate processing method as claimed in claim 2, wherein the metal in the film includes one of Ti, Ta, and W.

4. The substrate processing method as claimed in claim 1, wherein the first processing medium includes a supercritical medium with an etching agent added.

5. The substrate processing method as claimed in claim 4, wherein the etching agent includes one of a chelating agent, a halogen compound, and an acid.

6. The substrate processing method as claimed in claim 5, wherein the chelating agent includes H(hexafluoroacetylacetonate).

7. The substrate processing method as claimed in claim 5, wherein the halogen compound includes ClF₃.

8. The substrate processing method as claimed in claim 5, wherein the acid includes HCl.

9. The substrate processing method as claimed in claim 1, wherein the first step further comprises:
a step of removing the first processing medium and a reaction by-product on the surface of the substrate by the supercritical medium after the cleaning with the first processing medium.

10. The substrate processing method as claimed in claim 1, wherein the second processing medium includes the supercritical medium added with a precursor compound including copper.

11. The substrate processing method as claimed in claim 10, wherein the precursor compound including copper includes one of Cu⁺²(hexafluoroacetylacetonate)₂, Cu⁺² (acetylacetonate)₂, and Cu⁺²(2, 2, 6, 6-tetramethyl-3, 5-heptanedione)₂.

12. The substrate processing method as claimed in claim 10, wherein
the precursor compound including copper includes Cu⁺¹ (hexafluoroacetylacetonate) and silylolefin ligands, and
the silylolefin ligands include materials selected from trimethylvinylsilane (tmvs), allyloxytrimethylsilyl (aotms), dimethylacethylene (2-buthyne), 2-methyl-1-hexyne-3-yn (MHY), 3-hexyne-2, 5-dimethoxy (HDM), 1, 5-cyclooctadiene (1, 5-COD), and vinyltrimethoxyxilane (VTMOS).

13. The substrate processing method as claimed in claim 1, wherein the second step further comprises:
a step of removing the second processing medium and a reaction by-product on the surface of the substrate by the supercritical medium after forming the copper film.

14. The substrate processing method as claimed in claim 1, wherein the supercritical medium is supercritical carbon dioxide (CO₂).

15. The substrate processing method as claimed in claim 1, wherein
the first step and the second step are performed in a vessel for processing the substrate.

16. The substrate processing method as claimed in claim 1, wherein
the first step is performed in a vessel for processing the substrate, and the second step is performed in a different vessel.

17. A method of producing a semiconductor device, comprising:
a first step of supplying a first processing medium including a supercritical medium on a substrate to be processed, and cleaning a film on a surface of the substrate, said film including a metal; and
a second step of supplying a second processing medium including the supercritical medium on the substrate, and forming a copper film.

18. A recording medium including a program executable on a computer for controlling a processing device to execute:
a first step of supplying a first processing medium including a supercritical medium on a substrate to be processed, and cleaning a film on a surface of the substrate, said film including a metal; and
a second step of supplying a second processing medium including the supercritical medium on the substrate, and forming a copper film.

19. The recording medium as claimed in claim 18, wherein the film including a metal is a copper diffusion prevention film.

20. The recording medium as claimed in claim 19, wherein the metal in the film includes one of Ti, Ta, and W.

21. The recording medium as claimed in claim 18, wherein the first processing medium includes a supercritical medium added with an etching agent.

22. The recording medium as claimed in claim 21, wherein the etching agent includes one of a chelating agent, a halogen compound, and an acid.

23. The recording medium as claimed in claim 22, wherein the chelating agent includes H(hexafluoroacetylacetonate).

24. The recording medium as claimed in claim 22, wherein the halogen compound includes ClF₃.

25. The recording medium as claimed in claim 22, wherein the acid includes HCL.

26. The recording medium as claimed in claim 18, wherein the first step further comprises:
a step of removing the first processing medium and a reaction by-product on the surface of the substrate by the supercritical medium after the cleaning with the first processing medium.

27. The recording medium as claimed in claim 18, wherein the second processing medium includes the supercritical medium added with a precursor compound including copper.

28. The recording medium as claimed in claim 27, wherein the precursor compound including copper includes one of Cu⁺² (hexafluoroacetylacetonate)₂, Cu⁺² (acetylacetonate)₂, and Cu⁺² (2, 2, 6, 6-tetramethyl-3, 5-heptanedione)₂.

29. The recording medium as claimed in claim 27, wherein
the precursor compound including copper includes Cu⁺¹ (hexafluoroacetylacetonate) and silylolefin ligands, and
the silylolefin ligands include materials selected from trimethylvinylsilane (tmvs), allyloxytrimethylsilyl (aotms), dimethylacethylene (2-buthyne), 2-methyl-1-hexyne-3-yn (MHY), 3-hexyne-2, 5-dimethoxy (HDM), 1, 5-cyclooctadiene (1, 5-COD), and vinyltrimethoxyxilane (VTMOS).

30. The recording medium as claimed in claim 18, wherein the second step further comprises:
a step of removing the second processing medium and a reaction by-product on the surface of the substrate by the supercritical medium after forming the copper film.

31. The recording medium as claimed in claim 18, wherein the supercritical medium is supercritical carbon dioxide (CO₂).
